(19) United States
(12) Patent Application Publication
(10) Pub. No.: US 2019/0096918 A1
(43) Pub. Date: Mar. 28, 2019

(54) AN ARRAY SUBSTRATE, MASK PLATE AND ARRAY SUBSTRATE MANUFACTURING METHOD

(71) Applicant: Wuhan China Star Optelectronics Technology Co., Ltd., Wuhan, Hubei (CN)

(72) Inventor: Xinghua LIU, Shenzhen, Guangdong (CN)

(21) Appl. No.: 15/740,267

(22) PCT Filed: Nov. 24, 2017
(86) PCT No.: PCT/CN2017/112849

§ 371 Date: Dec. 27, 2017

(30) Foreign Application Priority Data
Sep. 27, 2017 (CN) 201710892062.1

(51) Int. Cl. H01L 27/12; H01L 29/423; H01L 29/786

(52) U.S. Cl. CPC H01L 27/1218; H01L 29/78651; H01L 29/42384; H01L 27/1288

(57) ABSTRACT

This invention provides a kind array substrate, includes a substrate, a thin film transistor layer disposed on the substrate, and a planarization layer disposed above the thin film transistor layer. A side surface of the planarization layer away from the thin film transistor layer formed a bump point. Pass through the set bumps, pass through the bumps on the surface of the flat layer form a diffuse reflection layer, which can weaken the reflection phenomenon and reduce the backlight requirement. This invention further provides a mask plate and a method to prepare the array substrate by using the mask plate.

### RELATED APPLICATIONS

The present application is a National Phase of International Application Number PCT/CN2017/112849, filed Nov. 24, 2017, and claims the priority of China Application No. 201710892062.1, filed Sep. 27, 2017.

### FIELD OF THE DISCLOSURE

The disclosure belongs to the field of flat panel display technology, and in particular relates to an array substrate, mask plate and a method for fabricating an array substrate.

### BACKGROUND

Low Temperature Poly-silicon (LTPS) thin-film transistor liquid crystal display is in the packaging process, to make use of excimer laser as a heat source. After the laser light passes through the projection system, will produce an energy evenly distributed laser beam, projected on a glass substrate of amorphous silicon structure, when after the amorphous silicon structure of the glass substrate absorbs the energy of the excimer laser, it will transform into a polysilicon structure, its biggest advantage is ultra-thin, light weight, low power consumption, can provide more beautiful colors and clearer image. The closed structure of the LTPS display in the industry generally includes a planarization layer covering the source/drain. The thickness of the planarization layer photoresist film is 2.5 um, and after baking the thickness uniformity of the planarized layer photoresist film is within 10%, which ensures the penetration rate requirement, and then meet the optical standards. In the current LTPS technology, because of the planar structure is adopted for the planarization layer, resulting in a reflectivity rate too low of the inner surface facing the backlight source, requiring a large amount of backlight and high cost. In the meantime, in the case of strong external light, to use the planarized layer of the flat structure designed with a flat structure is likely to cause reflection and affect the viewing of the screen.

### CONTENT OF THE INVENTION

In order to solve the problems of low reflectance and reflective light caused by the flat structure of the existing display screen, this invention provides an array substrate. The specific technical solution is as follows:

An array substrate comprising a substrate; a thin film transistor layer formed on the substrate; and a planarization layer formed above the thin film transistor layer;
a bump formed on side of the planarization layer away from the thin film transistor layer.

Preferably, the bumps are one or more of hemispherical, semi-elliptical, and tetrahedral pyramids.

Preferably, the hemispherical bumps have a diameter of 5-6 μm.

The bumps formed with regular concave and convex surfaces, and the subsequent layers keep the regular concave and convex surfaces. When external light is irradiated on the display screen, the concave and convex surfaces form a diffuse reflection layer to improve the light reflectivity and reduce the backlight requirement, and also weaken display reflective phenomenon, better watch affection.

Preferably, the thin film transistor layer comprises:
a buffer layer formed on the substrate;
   an active layer formed on the buffer layer;
a gate insulating layer formed on the buffer layer and covering the active layer;
agate formed on the gate insulating layer;
an interlayer insulating layer formed on the gate insulating layer and covering the gate, and a metal source/drain formed on the interlayer insulating layer.
   Preferably, a plurality of concaves are still formed on a surface of the planarization layer away from the thin film transistor layer, and the concaves and the bumps are arranged alternately.

Preferably, the concaves and bumps are over linked through a curve.

Preferably, a pitch between the bumps is smaller than a width of the bump.

Preferably, height from lowest point of the concave to highest point of the bumps is 0.7-1.3 μm.

This invention further provides a mask plate comprising an opaque region and a light-pervious region, the opaque region and the light-pervious region are set up periodically at intervals, the light-pervious region is light transmission or semi-light region.

Preferably, the opaque region and the light-pervious region are distributed in an approximately honeycomb structure, the approximate honeycomb structure comprises black grids, the black grids are separated by white edges, and the white edges belongs to the opaque region; a side edge of the black grid is 5-7 μm, and width of the white edge is smaller than the side edge of the black grid.

Preferably, the opaque region and the light-pervious region are in a checkerboard structure distribution, the checkerboard style structure comprises a black color grid and a white color grid, and the black grids and the white grids are mutual interval staggered setting; the black grids are located in the opaque area, and the white grids are located in the transparent area; the black color grid is a square grid with side length of 5-7 μm, and the white color grid is a side length of 5-7 μm square grid.

This invention also provides a method for fabricating an array substrate, the method comprising the steps of:
providing a substrate; sequentially depositing a buffer layer and an active layer on the substrate, sequentially forming a gate insulation layer, a gate electrode, an interlayer insulation layer, a metal source/drain electrode and a planarization layer on the substrate; forming bumps on surface of the planarization layer away from the metal source/drain by a photomask method; the mask plate is placed on top of the planarization layer, and the bumps are formed by yellow light and, etched production procedure.

Preferably, the active layer is to deposit an amorphous silicon layer on the buffer layer, then convert the amorphous silicon layer into a polycrystalline silicon layer and graphical to form a polysilicon segment, and form source/drain contact regions at both ends of the polysilicon segment.

The advantages of the disclosure are

(1) It will make the product flat layer to have regular concave-convex surface, so that the subsequent layers to maintain the regular concave-convex surface. In a specified perspective can effectively improve the light diffuse reflection, reducing the need of backlight quantity under the strong light; reduce energy consumption, products can effectively improve the product power endurance, extend the life of backlight components, and reduce the cost of backlight components. When the shine of the backlight source irradiates on the back of the concave-convex point of the flat layer, the shine of the backlight will have the reflected and refracted phenomenon on the reverse side of the bump, thus increasing the light brightness and further reducing the backlight requirement.

(2) It improves the surface of the display in the case of a relatively strong external light reflective problems, make the display image more clear and better viewing affection.

(3) It uses the arrangement way of concave-convex point is easier to create the diffuse mirror surface, easier to achieve in process.

### FIGURE DESCRIPTION

To describe this invention embodiment, or technical solutions of current technology more clearly, the following briefly introduces the accompanying drawings required for describing the embodiment or the prior art. Obviously, the accompanying drawings in the following description are merely some embodiments of this invention, regarding to the common technician of this field and say, without giving any creative hard work, other drawings may be obtained based on these drawings.

FIG. 1 is this invention schematic diagram of an array substrate in a first embodiment; wherein, FIG. 1 is a substrate, 2 is a buffer layer, 3 is a gate insulating layer, 4 is an interlayer insulating layer, 5 is a planarization layer, and 51 is a bump point on the planarization layer. 52 is an edge groove on a flat layer 61 is a polycrystalline silicon segment, 62 is a gate, 63 is a metal source/drain, 64 is a metal line, 65 is a source/drain contact area.

FIG. 2 is the light diffuse reflection route schematic diagram of the FIG. 1 array substrate irradiated by external light.

FIG. 3 is a design schematic diagram mask plate for the array substrate shown in fabrication FIG. 1, wherein 70 is a mask plate, 71 is a black color lattice, and 72 is a white edge.

FIG. 4 is the obtained showing FIG. of product according to the design and manufacture of the mask plate in FIG. 3, in which 51 is a bump point and 52 is an edge groove.

FIG. 5 is a schematic diagram of light diffuse emission paths of an array substrate in a second embodiment of this invention, wherein, 8 indicates a flat layer, 51 indicates a bump point, and 82 indicates a pit point.

FIG. 6 is a schematic diagram of the design of a mask plate for the array substrate shown in fabrication FIG. 5, wherein, 91 is a black color grid and 92 is a white color grid.

FIG. 7 is an obtained showing FIG. of product according to the mask plate design in FIG. 6, wherein, 51 is a bump point and 82 is a pit point.

FIG. 8 is a flowchart of this invention for fabricating an array substrate.

### SPECIFIC IMPLEMENTATION METHODS

The accompanying drawings in the embodiments of this invention will be combined below, to the technical solutions of the embodiments of this invention carry on clearly and completely description, obviously the described embodiments were only a part of embodiments this invention but not all of the embodiments. According to the embodiments in this invention, the common technicians of this area under the premise of not having do the creative work to obtain all other embodiments, shall fall within the protection scope of this invention.

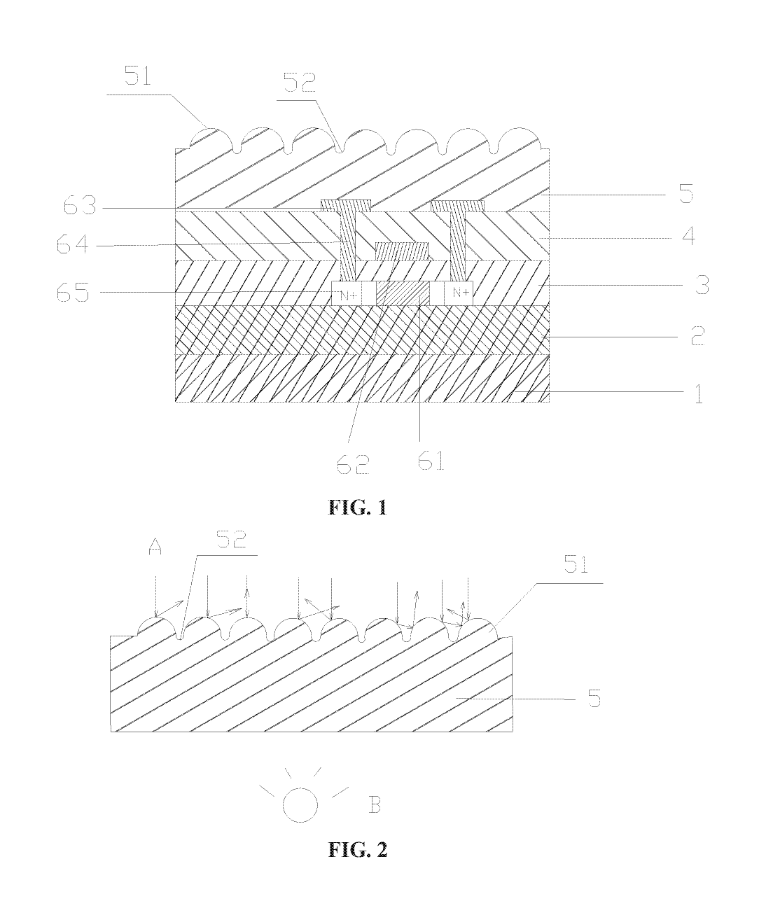

FIG. 1 is an array substrate provided by the first embodiment of this invention, the array substrate includes a substrate 1, a thin film transistor layer (not shown in figure) disposed on the substrate 1, and a planarization layer 5 disposed above the thin film transistor layer, a bump 51 is formed on one side surface of planarization layer 5 far away from the thin film transistor layer

In a progressing embodiment, the thin film transistor layer includes: a buffer layer 2 disposed on the substrate 1, an active layer (not shown in figure) disposed on the buffer layer 1, and the active layer includes a polysilicon segment 61 disposed on the surface of active layer 2 that reverse to the substrate 1 and the source/drain electrode contact area 65 disposed on the buffer layer 2 and located at opposite ends of the polysilicon section 61. The array substrate further includes a gate insulating layer 3 disposed on the surface of the buffer layer 2 reverse to the substrate 1 and covered by the active layer, and the gate 62 disposed on the surface of the gate insulating layer 3 reverse to the buffer layer 2. And the interlayer insulating layer 4 which covers the gate 62 and disposed on the surface of the gate insulating layer 3 reverse to the buffer layer 2. The array substrate further includes a metal source/drain 63 disposed on the surface of the interlayer insulating layer 4 reverse to the gate insulating layer 3 and flat layer 5 that covered metal source/drain 63 and disposed on the surface of the interlayer insulating layer 4 reverse to the gate insulating layer 3.

In a progressing embodiment, the buffer layer 2 further comprises a device light-shielding layer, the device light-shielding layer is directly under the active layer for protecting the active layer to avoid prolonged backlight source Irradiation and cause performance problems.

The metal source/drain 63 is electrically connected to the source/drain 65 by a metal line 64 that passes through the interlayer insulating layer 4. The polysilicon segment 61, the source/drain contact region 65, the gate electrode 62 and the metal source/drain electrode 63 together form a driving TFT.

The upwards bump on the surface of planarization layer 5 that away from the interlayer insulating layer 4 formed the bump 51, to let the surface of the planarization layer 5 as concave-convex surface. As shown in FIG. 2, when external light irradiated on the display screen along the A direction to reach the planarization layer 5, the concave-convex surface formed by the bumps 51 to the external light proceed diffusion, and at the same time, when the light irradiated by backlight B pass through the substrate 1, the buffer layer 2, the gate insulating layer 3 and the interlayer insulating layer 4 and irradiated to the planarization layer 5, the inside of concave-convex surface formed by the bump 51 proceed diffusion to the light from the backlight source so to improve backlight light reflection rate, in this case, simultaneously while reducing the backlight needs, but also weakened the display reflective phenomenon, the better viewing affection.

In this embodiment, the bumps 51 are hemispherical in shape, and the Interval settings between the two adjacent bumps 51. As shown in FIG. 4, along the X-axis direction or the Y-axis direction, the distance of two adjacent bumps interval settings is less than the width of the bump 51. It is understandable that the bumps in this invention may be regular patterns such as semi-oval, quadrangular pyramid and the like. As long as they are arranged in a regular pattern, can be the semi-elliptical, the quadrangular pyramid, or the different shape structures mixed alternately setting, for example, along with the X-axis direction or the Y-axis direction the semi-elliptical bumps and the quadrangular pyramid bumps are arranged in alternately setting.

Preferably, the bumps 51 are periodically and uniformly distributed so as to make the light passing through the flat layer 5 and the diffused light by the flat layer 5 more uniform, so as to obtain a better viewing effect (as shown in FIG. 2).

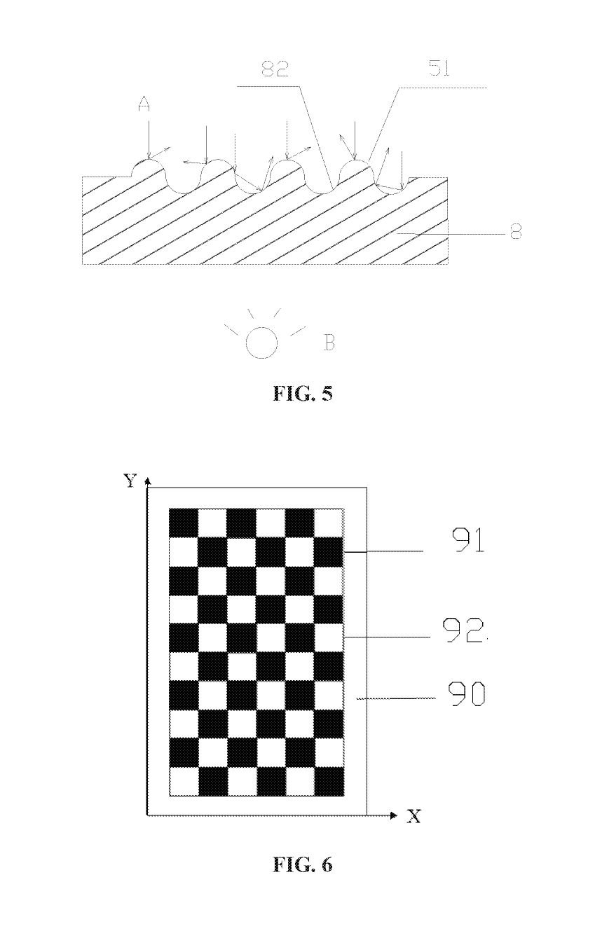

As shown in FIG. 5, the second embodiment provided by this invention is a further improvement based on the first embodiment. Specifically, in order to make the external light and the backlight source emitted light that all can form almost the same scattering effect, between the two adjacent bumps 51 are concavely formed into substantially hemispherical concave spots 82. The bumps 51 form periodically distributed convex surfaces and the concave 82 form periodically distributed concave surfaces when view from the side far from the interlayer insulating layer 4 of the flat layer 5; when view from the side near the interlayer insulating layer 4 of the flat layer 5, the concave 82 form periodic distribution convex surfaces and the bumps 51 form periodic faceted concave surfaces, so that to form regular concave-convex surface.

In a further embodiment, the bumps 51 and the concave 82 are connected by curves. The concave 82 are hemispherical concave downward. It can be understood that the concave 82 are not limited to the hemispherical shape, but may be one or more of semi-elliptical spherical shape and four-sided tapered shape.

In a further embodiment, the hemispherical shape of the bump 51 has a diameter of 5-6 μm. According to the current size specification of each pixel, it is a preferable technical solution to make the hemispherical diameter of the bump 51 the above specification.

In a further embodiment, the height from the lowest point of the pit point 82 to the highest point of the bump is 0.7-1.3 μm.

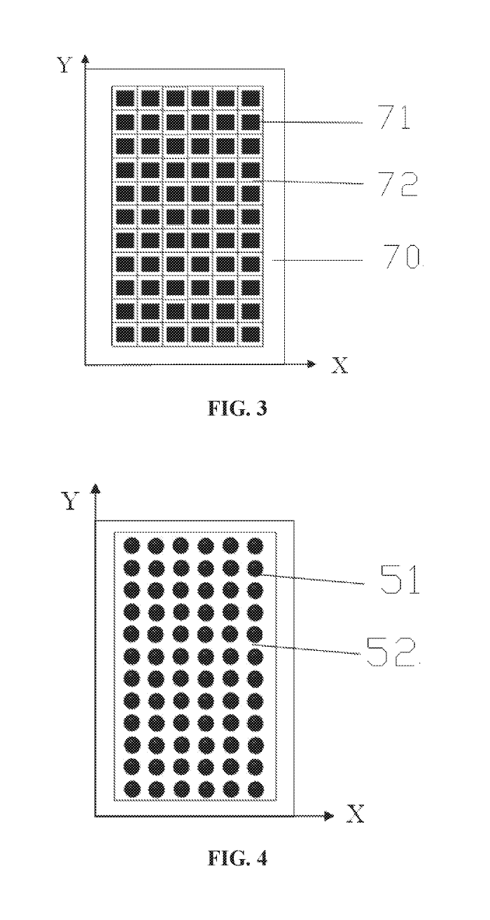

This invention further provides a mask plate 70, as shown in FIG. 3, the mask plate 30 includes an opaque area and a light-pervious area, the opaque area and the light-pervious area are spaced apart from each other by a periodicity setting, the transparent area is a light transmission area or semi-light transmission area.

Referring to FIG. 3 and FIG. 4, in the third embodiment of this invention, a first mask plate 70 is provided. The opaque regions and the light-permeable regions in the mask plate 70 are distributed in an approximate honeycomb structure, the approximate honeycomb structure comprises a black color grid 71 separated by white edges 72, the black color grid 71 is an area where the opaque area is located, and the white edge 72 is an area where the transparent area is located; The black color grid 71 is a square grid with a side length of 5-7 μm, and the white color grid 72 has a width smaller than that of a black color grid. In the present embodiment, the mask plate uses the approximate honeycomb structure setting and can let target product to use the concave-convex surface of concave-convex point interval formed after through photomask method production procedure of the mask plate.

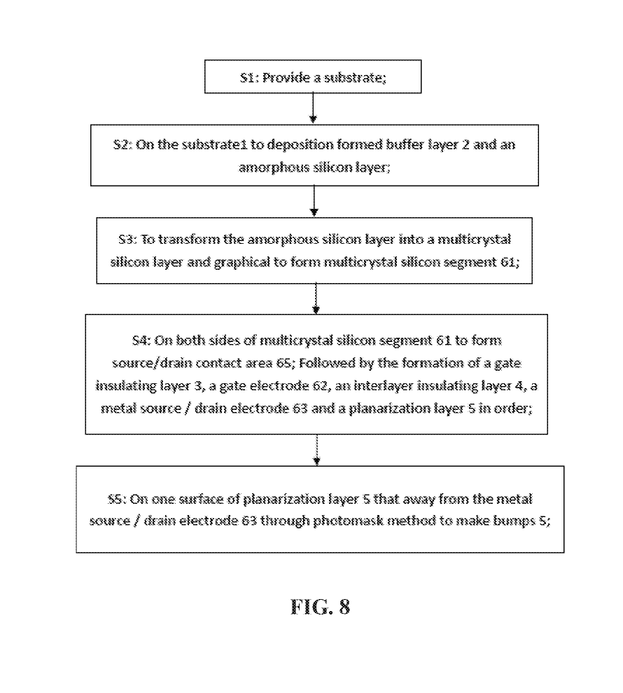

Please refer to FIGS. 3, 4 and 8, this invention provides a method for fabricating a first array substrate, comprising the steps of:

S1: providing a substrate 1;

S2: depositing a buffer layer 2 and an amorphous silicon layer on the substrate 1;

S3: converting the amorphous silicon layer into a polysilicon layer and patterning to form a polysilicon segment 61;

S4: forming source/drain contact regions 65 at both ends of the polysilicon segment 61, subsequently forming a gate insulating layer 3, a gate electrode 62, an interlayer insulating layer 4, a metal source/drain electrode 63 and a planarization layer 5 in sequence;

S5: A bump 5 is formed on the surface of the planarization layer 5 away from the metal source/drain electrode 63 by a photomask method. In this embodiment, the bump 5 are hemispherical; the photomask method uses the first kind mask plate 70 described above to place the mask plate 70 above the planar layer 5, and passes through yellow light, and etching manufacture procedure to form bump 51 and the edge groove 52 which separated the bumps 51. This method preparation is used to obtain the array substrate as shown in FIG. 1.

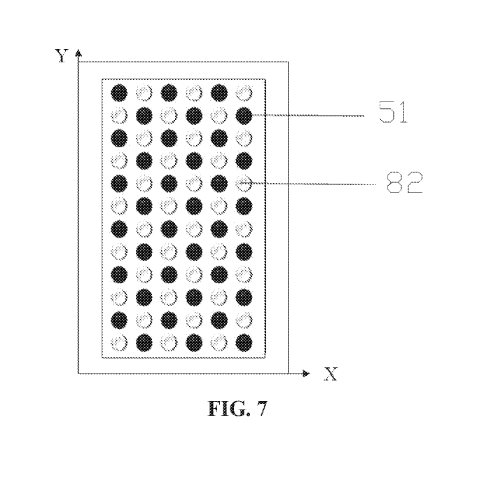

Please refer to FIGS. 6 and 7, in the fourth embodiment of this invention, to provide a second kind mask plate 90. The opaque areas and the light-permeable areas in the mask plate 90 are in a checkerboard structure distribution. The checkerboard structure includes a black color grid 91 and a white color grid 92 which are alternately in interval mixed setting. The black color grid 91 is an area where the opaque area is located, and the white color grid 92 is an area where light-permeable area is located; The black color grid 91 is a square grid with a side length of 5-7 μm, and the white color grid 92 is a square grid with a side length of 5-7 μm. The mask plate of this embodiment used the checkerboard structure setting can let the target product adopting the mask plate to carry on photomask method manufactured procedure afterwards to form the concave-convex surface separated by the concave-convex point.

Please refer to FIGS. 5 to 8, this invention provides a second kind fabricating method of array substrate, which is about the same as the fabricating method of the first array substrate, except that in the photomask method in step S5, in this embodiment photomask method is the use of the second kind mask plate 90 described above, the mask plate 90 is placed above the flat layer 5, through the yellow light, the etching manufactured procedure to form the bump 51 and pit point 82. Use this method preparation to obtain the including array substrate of the planar layer structure as shown in FIG. 5.

The above mentioned is the preferred embodiment of this invention. It should be noted that to those common technicians of this art area to say, under the premise without departing from the principle of the present invention, can make various improvements and retouch and these improvements and retouch are also the protection scope of this invention.

What is claimed is:

1. An array substrate comprising
a substrate;
a thin film transistor layer formed on the substrate; and
a planarization layer formed above the thin film transistor layer;
a bump formed on a surface of one side of the planarization layer away from the thin film transistor layer.

2. The array substrate according to claim 1, wherein the thin film transistor layer comprises:
a buffer layer formed on the substrate;
an active layer formed on the buffer layer;
a gate insulating layer formed on the buffer layer and covering the active layer;
a gate electrode formed on the gate insulating layer;
an interlayer insulating layer formed on the gate insulating layer and covering the gate electrode, and a metal source/drain formed on the interlayer insulating layer.

3. The array substrate according to claim 1, wherein a plurality of concaves are still formed on the surface of one side of the planarization layer away from the thin film transistor layer, and the concaves and the bumps are arranged alternately.

4. The array substrate according to claim 3, wherein the concaves and bumps are over linked through a curve.

5. The array substrate according to claim 1, wherein a pitch between the bumps is smaller than a width of the bump.

6. The array substrate according to claim 3, wherein a height from lowest point of the concave to highest point of the bumps is 0.7-1.3 μm.

7. A mask plate, comprising an opaque region and a light-pervious region, the opaque region and the light-pervious region are set up periodically at intervals, the light-pervious region is a light transmission region or a semi-light transmission region.

8. The mask plate according to claim 7, wherein the opaque region and the light-pervious region are distributed in an approximately honeycomb structure, the approximate honeycomb structure comprises black grids, the black grids are separated by white edges, the black grids are located in the opaque region and the white edges are located in the light-previous region; a side length of the black grid is 5-7 μm, and a width of the white edge is smaller than the side length of the black grid.

9. The mask plate according to claim 7, wherein the opaque region and the light-pervious region are in a checkerboard structure distribution, the checkerboard structure comprises black grids and white grids disposed at intervals; the black grids are located in the opaque area, and the white grids are located in the light-pervious region area; the black grid is a square grid with side length of 5-7 μm, and the white grid is a square grid with side length of 5-7 μm.

10. A method for fabricating an array substrate, wherein, the method comprises steps:
providing a substrate;
sequentially depositing a buffer layer and an active layer on the substrate, sequentially forming a gate insulation layer, a gate electrode, an interlayer insulation layer, a metal source/drain electrode and a planarization layer on the substrate;
forming bumps on surface of the planarization layer away from the metal source/drain by a photomask method; wherein the photomask method adopts the mask plate of claim 7, the mask plate is placed on top of the planarization layer, and the bumps are formed by yellow light lithography and etching procedures.
